(19) United States
(12) Patent Application Publication
(10) Pub. No.: US 2023/0300999 A1
(43) Pub. Date: Sep. 21, 2023

(54) ELECTRONIC DEVICE

(71) Applicant: PEGATRON CORPORATION, Taipei City (TW)

(72) Inventor: HSIN-MIN TIEN, Taipei City (TW)

(21) Appl. No.: 18/157,455

(22) Filed: Jan. 20, 2023

(30) Foreign Application Priority Data
Mar. 21, 2022 (TW) 111110413

(51) Int. Cl. H05K 5/02

(52) U.S. Cl. CPC H05K 5/0212

(57) ABSTRACT

Disclosed in the present disclosure is an electronic device, including a case, an electronic component, a cellulose acetate plate and an insulating layer. The case includes an opening and an accommodating space, a position of the opening corresponding to the accommodating space. The electronic component is arranged in the accommodating space. The cellulose acetate plate is arranged at the opening, a spacing distance being provided between the cellulose acetate plate and the electronic component. The cellulose acetate plate has an upper surface. The insulating layer is arranged at the opening and the upper surface of the cellulose acetate plate, and is arranged between the cellulose acetate plate and the case to insulate the cellulose acetate plate from an external environment.

### TECHNICAL FIELD

The present disclosure relates to an electronic device.

### BACKGROUND

Generally, an electronic device frequently used outdoors may encounter dew condensation and fogging, causing impact on some functions. For example, a display screen of a vehicle dashboard is arranged inside a case. The case has an appearance (transparent) panel. A user can view information on the display screen through the appearance panel. The display screen and the appearance panel are arranged at an interval to provide air isolation between the display screen and the appearance panel, thereby protecting the internal display screen or other electronic components. However, when relative humidity is high or an ambient temperature changes rapidly, air inside an electronic device (such as a dashboard) tends to condense into dewdrops on the appearance panel. This phenomenon of dew condensation and fogging prevents the user from viewing content on the display screen through the appearance panel.

In addition, for a lens module of a camera or a monitor, an appearance protective film and an internal electronic component (such as an image sensor or a circuit board) are also arranged at an interval, and air is present between the protective film and the electronic component. Similarly, when the relative humidity is high or the ambient temperature changes rapidly, air in the lens module tends to condense into dew and fog on the protective film, causing an impact on a captured image picture.

### SUMMARY

In view of the foregoing subject, the main objective of the present disclosure is to provide an electronic device, which solves the problem that a conventional electronic device is prone to dew condensation and fogging due to an ambient temperature by arranging a cellulose acetate plate (or a cellulose acetate layer) and an insulating layer.

To achieve the foregoing objective, the present disclosure provides an electronic device, including a case, an electronic component, a cellulose acetate plate, and an insulating layer. The case includes an opening and an accommodating space, a position of the opening corresponding to the accommodating space. The electronic component is arranged in the accommodating space. The cellulose acetate plate is arranged at the opening, a spacing distance being provided between the electronic component and the cellulose acetate plate. The cellulose acetate plate has an upper surface. The insulating layer is arranged at the opening and the upper surface of the cellulose acetate plate, and is arranged between the cellulose acetate plate and the case to insulate the cellulose acetate plate from an external environment.

According to an embodiment of the present disclosure, the cellulose acetate plate has at least one side surface. The insulating layer extends from the upper surface of the cellulose acetate plate and is arranged between the side surface of the cellulose acetate plate and the case.

According to an embodiment of the present disclosure, the electronic component includes a display panel, a circuit board, or an image sensor.

According to an embodiment of the present disclosure, the insulating layer includes a waterproof clear coating.

To achieve the foregoing objective, the present disclosure further provides an electronic device, including a case, an electronic component, a light-transmissible plate, a cellulose acetate layer, and an insulating layer. The case includes an opening and an accommodating space, a position of the opening corresponding to the accommodating space. The electronic component is arranged in the accommodating space. The light-transmissible plate is arranged at the opening and has a lower surface and an upper surface. The cellulose acetate layer is arranged on the lower surface of the light-transmissible plate, a spacing distance being provided between the cellulose acetate layer and the electronic component. The insulating layer is arranged on the upper surface of the light-transmissible plate and at least part of the case to insulate the cellulose acetate layer from an external environment.

According to an embodiment of the present disclosure, the cellulose acetate layer includes a cellulose acetate plate or a cellulose acetate membrane.

According to an embodiment of the present disclosure, the cellulose acetate layer has at least one side surface. The insulating layer extends from the upper surface of the light-transmissible plate and is arranged between the side surface of the cellulose acetate layer and the case.

According to an embodiment of the present disclosure, the electronic component includes a display panel, a circuit board, or an image sensor.

According to an embodiment of the present disclosure, the light-transmissible plate includes a polycarbonate (PC) material, a poly(methyl methacrylate) (PMMA) material, or a glass material.

According to an embodiment of the present disclosure, the insulating layer includes a waterproof clear coating.

As mentioned above, the electronic device according to the present disclosure includes a case, an electronic component, an insulating layer, and a cellulose acetate plate or a cellulose acetate layer. The electronic component is arranged in an accommodating space of the case. The cellulose acetate plate is arranged at an opening of the case. The insulating layer is arranged at the opening and an upper surface of the cellulose acetate plate, and is arranged between the cellulose acetate plate and the case to insulate the cellulose acetate plate from an external environment. The electronic device may further include a light-transmissible plate arranged at the opening of the case. The cellulose acetate layer is arranged on a lower surface of the light-transmissible plate. The insulating layer is arranged on an upper surface of the light-transmissible plate and at least part of the case to insulate the cellulose acetate layer from the external environment. With the foregoing structure, the cellulose acetate plate and the cellulose acetate layer can absorb vapor and moisture in the accommodating space, and the insulating layer can prevent the cellulose acetate plate from absorbing vapor in the external environment, thereby preventing dew condensation or fogging.

### BRIEF DESCRIPTION OF THE DRAWINGS

FIG. 1 is a schematic cross-sectional view of an electronic device according to a first embodiment of the present disclosure.

FIG. 2 is a schematic cross-sectional view of an electronic device according to a second embodiment of the present disclosure.

FIG. 3 is a schematic cross-sectional view of an electronic device according to a third embodiment of the present disclosure.

### DETAILED DESCRIPTION

To better understand the technical content of the present disclosure, the preferred specific embodiments are described below. The specific implementations of the present disclosure are further described below with reference to the accompanying drawings and the embodiments. The following embodiments are merely used for more clearly describing the technical solutions of the present disclosure, and are not intended to limit the protection scope of the present disclosure.

For convenience and clarity of the description, maximum widths or sizes of the elements in the drawings expressed in an exaggerated, omitted or general manner are used to help a person skilled in the art to understand and read, and the sizes of the elements are not completely actual sizes and are not intended to limit restraint conditions under which the present disclosure can be implemented and therefore have no technical significance. Any modification to the structure, change to the proportional relationship or adjustment on the size should fall within the scope of the technical content disclosed by the present disclosure without affecting the effects and the objectives that can be achieved by the present disclosure. The same reference numeral is used to indicate the same or similar elements in all of the drawings.

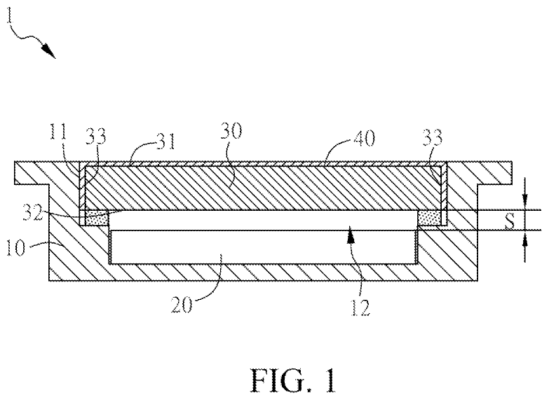

FIG. 1 is a schematic cross-sectional view of an electronic device according to a first embodiment of the present disclosure, and reference is made to FIG. 1. First, the electronic device 1 in this embodiment may be an electronic device frequently used outdoors, which may be, for example, but not limited to, a dashboard, a camera, a monitor, or the like. For example, the electronic device 1 in this embodiment is a dashboard. The electronic device 1 includes a case 10, an electronic component 20, a cellulose acetate plate 30, and an insulating layer 40. The case 10 includes an opening 11 and an accommodating space 12. A position of the opening 11 corresponds to the accommodating space 12. It should be noted that the opening 11 shown in FIG. 1 is marked on an inner wall of the case 10. For example, the electronic component 20 in this embodiment is a display screen. The electronic component 20 is arranged in the accommodating space 12. In another embodiment, if the electronic device 1 is a device such as a camera, or a monitor, the electronic component 20 may be a circuit board of a lens module or an image sensor.

The cellulose acetate plate 30 is arranged at the opening 11. A spacing distance S is provided between the cellulose acetate plate 30 and the electronic component 20. Specifically, the cellulose acetate plate 30 has an upper surface 31 and a lower surface 32. The upper surface 31 is located in the opening 11 of the case 10, and the lower surface 32 faces the electronic component 20. The spacing distance S is provided between the lower surface 32 of the cellulose acetate plate 30 and the electronic component 20. The cellulose acetate plate 30 is a plate body made of cellulose acetate. For one characteristic of the cellulose acetate plate 30, the cellulose acetate plate 30 may be a transparent material, which may be used as an appearance panel of the dashboard. In another embodiment, the cellulose acetate plate 30 may be used as an appearance protective film of the lens module. In other words, the electronic device 1 in this embodiment may be applied to the device in which the spacing distance S is provided between the appearance panel or the appearance protective film and the internal electronic component 20. The electronic device 1 for outdoor use usually has a structure in which the spacing distance S is provided between the appearance panel or the protective film and the internal electronic component 20. Actually, outdoor use is not a necessary limitation.

In addition, for another characteristic, the cellulose acetate plate 30 can absorb moisture and vapor, thereby absorbing vapor and moisture inside the accommodating space 12. Specifically, even if air in the accommodating space 12 condenses into dewdrops on the cellulose acetate plate 30 due to a rapid change in an ambient temperature, the dewdrops may be immediately absorbed by the cellulose acetate plate 30, thereby avoiding dew condensation or fogging.

In addition, the insulating layer 40 is arranged at the opening 11 and the upper surface 31 of the cellulose acetate plate 30, and is arranged between the cellulose acetate plate 30 and the case 10 to insulate the cellulose acetate plate 30 from an external environment. Specifically, the cellulose acetate plate 30 further has at least one side surface 33. The cellulose acetate plate 30 in this embodiment may be a quadrilateral plate body with four side surfaces 33. FIG. 1 is a cross-sectional view showing two opposite side surfaces 33. The insulating layer 40 extends from the upper surface 31 of the cellulose acetate plate 30 and is arranged between the side surface 33 of the cellulose acetate plate 30 and the case.

The insulating layer 40 may be made of a waterproof material to insulate vapor and moisture in the external environment. The insulating layer 40 may be a waterproof clear coating. For example, the waterproof clear coating may be sprayed on the upper surface 31 and the side surface 33 of the cellulose acetate plate 30 to form the insulating layer 40. Next, the cellulose acetate plate 30 sprayed with the insulating layer 40 (the waterproof clear coating) is arranged at the opening 11 of the case 10, so that the cellulose acetate plate 30 and the insulating layer 40 are arranged at the opening 11, and the insulating layer 40 is further arranged between the cellulose acetate plate 30 and the case 10. The insulating layer 40 is arranged on the upper surface 31 of the cellulose acetate plate 30 and arranged between the cellulose acetate plate 30 and the case 10 to insulate the cellulose acetate plate 30 from the external environment, thereby preventing the cellulose acetate plate 30 from absorbing vapor and moisture in the external environment.

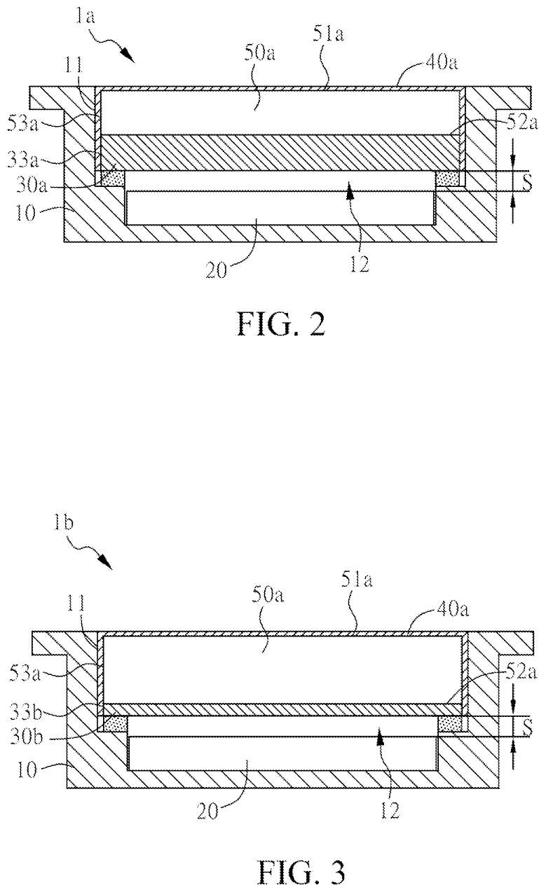

FIG. 2 is a schematic cross-sectional view of an electronic device according to a second embodiment of the present disclosure, and reference is made to FIG. 2. The electronic device 1a in this embodiment includes a case 10, an electronic component 20, a cellulose acetate layer 30a, an insulating layer 40a, and a light-transmissible plate 50a. The case 10 and the electronic component 20 are the same as those in the foregoing embodiment, and the reference numerals continue to be used. For details, reference may be directly made to the foregoing embodiment. The main difference between this embodiment and the first embodiment is that the electronic device 1a in this embodiment further includes the light-transmissible plate 50a, and makes the arrangement positions of the cellulose acetate layer 30a and the insulating layer 40a slightly different from those of the cellulose acetate plate 30 and the insulating layer 40 in the first embodiment.

Specifically, the light-transmissible plate 50a is arranged at the opening 11 of the case 10. The light-transmissible plate 50a may be made of, for example, but not limited to, a polycarbonate (PC for short) material, a poly(methyl methacrylate) (PMMA for short) material, or a glass material. That is, the light-transmissible plate 50a may be, for example, a PC plate, a PMMA plate, or a glass plate, which all have the common characteristics of being transparent and light-transmissible, and therefore may be used as the appearance panel of the electronic device 1.

The light-transmissible plate 50a has an upper surface 51a and a lower surface 52a. The cellulose acetate layer 30a is arranged on the lower surface 52a of the light-transmissible plate 50a. In other words, the cellulose acetate layer 30a is located in the accommodating space 12 of the case 10 and is located on the lower surface 52a of the light-transmissible plate 50a. The cellulose acetate layer 30a is a layer made of cellulose acetate. The cellulose acetate layer 30a in this embodiment may be the same as that in the first embodiment, which is the cellulose acetate plate. The cellulose acetate layer 30a is also light-transmissible and transparent material, so that a user can view display information on the electronic component 20 through the light-transmissible plate 50a and the cellulose acetate layer 30a. Similarly, the spacing distance S is provided between the cellulose acetate layer 30a and the electronic component 20. The cellulose acetate layer 30a is arranged on the lower surface 52a of the light-transmissible plate 50a to absorb moisture and vapor inside the accommodating space 12. In addition, moisture inside the accommodating space 12 can be prevented from forming dewdrops on the surface of the light-transmissible plate 50a, thereby avoiding dew condensation or fogging.

The insulating layer 40a in this embodiment is arranged on the upper surface 51a of the light-transmissible plate 50a and at least part of the case 10 to insulate the cellulose acetate layer 30a from an external environment, thereby preventing the cellulose acetate layer 30a from absorbing vapor and moisture in the external environment. Specifically, the cellulose acetate layer 30a has at least one side surface 33a, and the light-transmissible plate 50a also has at least one side surface 53a. The cellulose acetate layer 30a and the light-transmissible plate 50a in this embodiment are quadrilateral plate bodies, and have four side surfaces 33a and 53a respectively. The insulating layer 40a extends from the upper surface 51a of the light-transmissible plate 50a and is arranged between the side surface 53a and the case 10, and further extends and is arranged between the side surface 33a of the cellulose acetate layer 30a and the case 10.

Similarly, the insulating layer 40a may be a waterproof clear coating. For example, after the cellulose acetate layer 30a is arranged on the light-transmissible plate 50a, the waterproof clear coating is sprayed on the upper surface 51a and the side surface 53a of the light-transmissible plate 50a and the side surface 33a of the cellulose acetate layer 30a to form the insulating layer 40a. Next, the light-transmissible plate 50a is arranged at the opening 11 of the case 10, so that the cellulose acetate layer 30a is located in the accommodating space 12. In this case, the insulating layer 40a is located on the upper surface 51a of the light-transmissible plate 50a and on the side surface 53a of the light-transmissible plate 50a and the side surface 33a of the cellulose acetate layer 30a.

FIG. 3 is a schematic cross-sectional view of an electronic device according to a third embodiment of the present disclosure, and reference is made to FIG. 3. The electronic device 1b in this embodiment includes a case 10, an electronic component 20, a cellulose acetate layer 30b, an insulating layer 40a, and a light-transmissible plate 50a. The case 10 and the electronic component 20 are the same as those in the first embodiment, and the reference numerals continue to be used. The insulating layer 40a and the light-transmissible plate 50a are the same as those in the second embodiment, and the reference numerals continue to be used. For details, reference may be directly made to the foregoing embodiment. The main difference between this embodiment and the second embodiment is that the cellulose acetate layer 30b in this embodiment is a cellulose acetate membrane.

After the cellulose acetate layer 30b (the cellulose acetate membrane) is bonded or coated on the light-transmissible plate 50a, the waterproof clear coating is sprayed on the upper surface 51a and the side surface 53a of the light-transmissible plate 50a and the side surface 33b of the cellulose acetate layer 30b to form the insulating layer 40a. Next, the light-transmissible plate 50a is arranged at the opening 11 of the case 10, so that the cellulose acetate layer 30b is located in the accommodating space 12. In this case, the insulating layer 40a is located on the upper surface 51a of the light-transmissible plate 50a and between the light-transmissible plate 50a, the cellulose acetate layer 30b and the case 10 to form the electronic device 1b in this embodiment. The cellulose acetate layer 30b (the cellulose acetate membrane) can also absorb moisture and vapor inside the accommodating space 12, and the insulating layer 40a can prevent the cellulose acetate layer 30b from absorbing vapor in an external environment, thereby preventing dew condensation or fogging.

In summary, the electronic device according to the present disclosure includes a case, an electronic component, an insulating layer, and a cellulose acetate plate or a cellulose acetate layer. The electronic component is arranged in an accommodating space of the case. The cellulose acetate plate is arranged at an opening of the case. The insulating layer is arranged at the opening and an upper surface of the cellulose acetate plate, and is arranged between the cellulose acetate plate and the case to insulate the cellulose acetate plate from an external environment. The electronic device may further include a light-transmissible plate arranged at the opening of the case. The cellulose acetate layer is arranged on a lower surface of the light-transmissible plate. The insulating layer is arranged on an upper surface of the light-transmissible plate and at least part of the case to insulate the cellulose acetate layer from the external environment. With the foregoing structure, the cellulose acetate plate and the cellulose acetate layer can absorb vapor and moisture in the accommodating space, and the insulating layer can prevent the cellulose acetate plate from absorbing vapor in the external environment, thereby preventing dew condensation or fogging.

It should be noted that many of the foregoing embodiments are examples for the convenience of description. The scope of the claims claimed in the present disclosure should be subject to the scope of the patent application, not limited to the foregoing embodiments.

What is claimed is:

1. An electronic device, comprising:
a case, comprising an opening and an accommodating space, a position of the opening corresponding to the accommodating space;
an electronic component, arranged in the accommodating space;
a cellulose acetate plate, arranged at the opening, a spacing distance being provided between the cellulose acetate plate and the electronic component, the cellulose acetate plate having an upper surface; and
an insulating layer, arranged at the opening and the upper surface of the cellulose acetate plate, and arranged between the cellulose acetate plate and the case to insulate the cellulose acetate plate from an external environment.

2. The electronic device according to claim 1, wherein the cellulose acetate plate has at least one side surface, and the insulating layer extends from the upper surface of the cellulose acetate plate and is arranged between the side surface of the cellulose acetate plate and the case.

3. The electronic device according to claim 1, wherein the electronic component comprises a display panel, a circuit board, or an image sensor.

4. The electronic device according to claim 1, wherein the insulating layer comprises a waterproof clear coating.

5. An electronic device, comprising:
a case, comprising an opening and an accommodating space, a position of the opening corresponding to the accommodating space;
an electronic component, arranged in the accommodating space;
a light-transmissible plate, arranged at the opening and having a lower surface and an upper surface;
a cellulose acetate layer, arranged on the lower surface of the light-transmissible plate, a spacing distance being provided between the cellulose acetate layer and the electronic component; and
an insulating layer, arranged on the upper surface of the light-transmissible plate and at least part of the case to insulate the cellulose acetate layer from an external environment.

6. The electronic device according to claim 5, wherein the cellulose acetate layer comprises a cellulose acetate plate or a cellulose acetate membrane.

7. The electronic device according to claim 5, wherein the cellulose acetate layer has at least one side surface, and the insulating layer extends from the upper surface of the light-transmissible plate and is arranged between the side surface of the cellulose acetate layer and the case.

8. The electronic device according to claim 5, wherein the electronic component comprises a display panel, a circuit board, or an image sensor.

9. The electronic device according to claim 5, wherein the light-transmissible plate comprises a polycarbonate (PC) material, a poly(methyl methacrylate) (PMMA) material, or a glass material.

10. The electronic device according to claim 5, wherein the insulating layer comprises a waterproof clear coating.
